(19) United States
(12) Patent Application Publication
(10) Pub. No.: US 2015/0335116 A1
(43) Pub. Date: Nov. 26, 2015

(54) PROTECTIVE CASE FOR MOBILE DEVICE

(71) Applicant: SAMSUNG ELECTRONICS CO., LTD., Gyeonggi-do (KR)

(72) Inventors: Byoung-woo Kim, Suwon-si, Gyeonggi-do (KR); Jeong-ho Kim, Suwon-si, Gyeonggi-do (KR); Wan-ju Byun, Suwon-si, Gyeonggi-do (KR); Sung-ho Jung, Gangdong-gu, Seoul (KR); Young-sang Cho, Yongin-si, Gyeonggi-do (KR)

(73) Assignee: SAMSUNG ELECTRONICS CO., LTD., Gyeonggi-do (KR)

(21) Appl. No.: 14/759,592

(22) PCT Filed: Jan. 7, 2014
(86) PCT No.: PCT/KR2014/000120

§ 371 Date: Jul. 7, 2015

(30) Foreign Application Priority Data
Jan. 7, 2013 (KR) 10-2013-0001811

(51) Int. Cl. A45C 11/00; H05K 5/03; A45F 5/00; H05K 5/00

(52) U.S. Cl. CPC A45C 11/00; H05K 5/0017; H05K 5/0086; H05K 5/03; A45F 5/00; A45C 2011/002; A45C 2011/003

(57) ABSTRACT

According to one embodiment of the present invention, a protective case for a mobile device comprises: a case body attached to the mobile device; and an external mount keypad unit which is arranged in the case body and which includes a plurality of key pads that are to be used in the mobile device.

### RELATED APPLICATIONS

This application is a U.S. National Phase of PCT Application No. PCT/KR2014/000120, filed Jan. 7, 2014, which claims priority to Korean application No. 10-2013-0001811, filed on Jan. 7, 2013, all of which are hereby incorporated by reference.

### TECHNICAL FIELD

Embodiments of the present disclosure relate to a protective case for a mobile device, and more specifically, to a protective case for a mobile device having an external mount keypad unit.

### BACKGROUND OF THE INVENTION

Touch screens have recently been adopted for the displays of mobile devices. Smart phone is a representative example of the mobile device having touch screen. A user is enabled to use the mobile device as he or she intends, as he or she can execute a program or application, or input texts, or the like, by touching the touch screen.

Meanwhile, those with visual disabilities or those who are restricted from watching the touch screen have considerable inconvenience and difficulties of using mobile devices, as it is practically impossible to use the mobile device without looking at the touch screen. Accordingly, a technology is necessary, which allows those with visual imp hose who are not able to watch the touch screen to use the touch-screen type mobile devices.

### BRIEF SUMMARY

### Technical Problem

Accordingly, an object of the present disclosure is to provide a protective case for a nubile device, which allows a user with visual disability or who is not able to watch a touch screen to use the mobile device without having to use the touch screen.

### Solution to Problem

In order to accomplish the above-mentioned objects, a protective case for a mobile device is provided, which may include a ease body attached to the mobile device, and an external mount keypad unit provided on the case body, and comprising a plurality of keypads for use of the mobile device.

The plurality of keypads may be arranged in M rows and N columns,wherein M and N are natural numbers which are equal to, or greater than 3.

At least one of the keypads arranged on a top row or a bottom row among the plurality of keypads may be provided with a protrusion to assist identification of a top of the external mount keypad unit from a bottom thereof.

The keypads arranged in a left-most side and in a right-most side among the N number of keypads arranged in the top row or the bottom row, may be provided with the protrusion.

The plurality of keypads may be used in any one of a first mode to access a program or an application of the mobile device, a second mode to input a first language-based text, and a third mode to input a second language-based text.

The plurality of keypads may be arranged in 4 rows and 3 columns.

When the plurality of keypads is used in the first mode, four out of the plurality of keypads may be used as up, down, left and right movement keypads.

When the plurality of keypads are used in the first mode, the up, down, left and right movement keypads may be arranged on an upper side, a lower side, a left side and a right side with reference to any one of the plurality of keypads.

The case body may be a rear surface cover type which covers a rear surface of the mobile device.

The external mount keypad unit may be provided on a rear surface of the case body.

The external mount keypad unit may be arranged closer to an upper end than to a lower end, on the rear surface of the case body.

The case body may be a double surface cover type which covers a front surface and a rear surface of the mobile device.

The case body may include a rear cover attached to the mobile device, covering a rear surface of the mobile device, and a front cover covering a front surface of the mobile device.

The external mount keypad unit may be provided on any one of a rear surface of the rear cover, a front surface of the front cover, and a rear surface of the front over.

The plurality of keypads may be protruded from the case body or concaved within the case body.

The mobile device may be a mobile phone having a touch screen.

### BRIEF DESCRIPTION OF SEVERAL VIEWS OF THE DRAWINGS

FIG. 1 is a perspective view of a protective case for a mobile device according to a first embodiment of the present disclosure, shown along with the mobile device.

FIG. 2 is a plan view of the protective case of FIG. 1 seen from behind.

FIG. 3A is a cross sectional view taken on line III-III of the protective case of FIG. 2.

FIG. 3B is a cross sectional view similar to FIG. 3A, illustrating an alternative embodiment of the embodiment illustrated in FIG. 3A.

FIG. 4A is a conceptual view illustrating functions designated by keypads when a plurality of keypads shown in FIG. 2 are used in the“first mode”.

FIG. 4B is a conceptual view illustrating functions designated by keypads when a plurality of keypads shown in FIG. 2 are used in the “second mode”.

FIG. 4C is a conceptual view illustrating functions designated by keypads when a plurality of keypads shown in FIG. 2 are used in the “third mode”.

FIGS. 5A, 5B and 5C are plan views of a mobile device, provided to explain a process of approaching a desired program or application using an external mount keypad unit illustrated in FIG. 2.

FIG. 6 is a perspective view of a protective case for a mobile device according to a second embodiment of the present disclosure, shown along with the mobile device.

FIG. 7 is a perspective view of the protective case of FIG. 6 in closed state.

### DETAILED DESCRIPTION

The embodiments of a protective case for a mobile device will be explained in greater detail below with reference to the drawings.

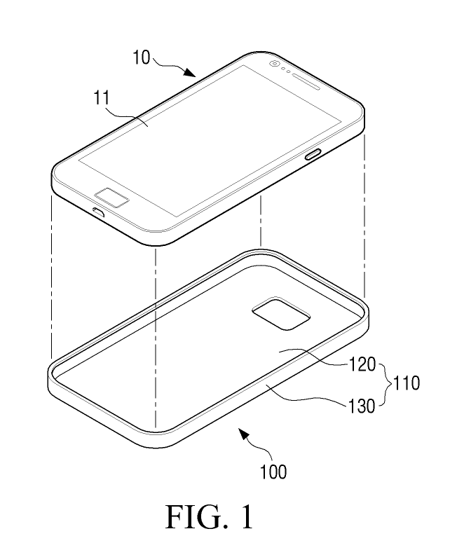

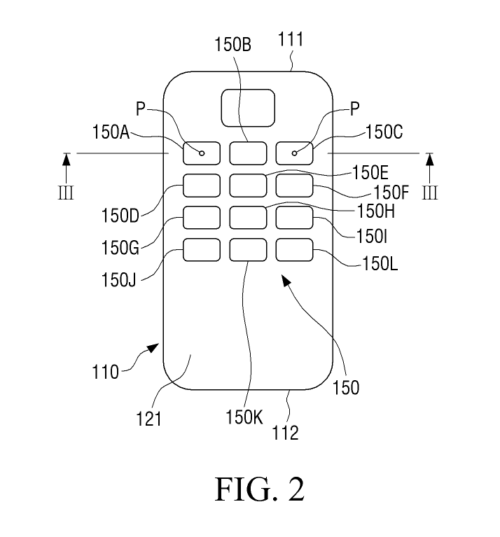

FIG. 1 is a perspective view of a protective case or a mobile device according to a first embodiment of the present disclosure, shown along with the mobile device, and FIG. 2 is a plan view of the protective case of FIG. 1 seen from behind.

FIG. 1 illustrates a mobile phone as an example of a mobile device 10 having a touch screen 11. However, the present disclosure is applicable to other types of mobile devices such as personal digital assistance (PDA), or tablet personal computer (PC).

Referring to FIGS. 1 and 2, a protective case 100 is illustrated, which is attached to the mobile device 100 for the purpose of protecting the mobile device 10. The protective case 100 is typically maintained being continuously attached to the mobile device 10, unless there is a special occasion such as removal of battery (not illustrated).

The protective case 100 includes a case body 110 and an external mount keypad unit 150.

The case body 110 includes a base portion 120 having a shape and a size corresponding to the mobile device 10, and an edge portion 130 vertically extended from a periphery of the base portion 120 to the base portion 120. The base portion 120 protects the mobile device 10 from external impact, by covering a rear surface of the mobile device 10. The edge portion 130 is coupled with four side surfaces of the mobile device 10 to protective the same and also to maintain the protective case 100 in its state of being attached to the mobile device 10. In order to allow easy attachment and detachment of the protective case 100 to and from the mobile device 10, the case body 110 generally has an elastic material (e.g., plastic, rubber, etc.) or the edge portion 130 of the case body 10 has an elastic material.

As illustrated in FIG. 2, the external mount keypad unit 150 is provided on a rear surface 121 of the case body 110. The rear surface 121 of the case body 110 is the rear surface of the base portion 120 of the case body 110. This external mount keypad unit 150 is provided to increase user's accessibility to the mobile device 10, or to be more specific, to enable those with visual impairment or those who are restricted from watching the touch screen 11, to use the mobile device 100 without having to use the touch screen 11.

The external mount keypad unit 150 includes a first keypad 150A, a second keypad 150B, a third keypad 150C, a fourth keypad 150D, a fifth keypad 150E, a sixth keypad 150F, a seventh keypad 150G, an eighth keypad 150H, a ninth keypad 150I, a tenth keypad 150J, an eleventh keypad 150K, and a twelfth keypad 150L. Accordingly, total twelve keypads are in the external mount keypad unit 150, although the number of the external mount keypad units 150 is not limited thereto, but is modifiable to a variety of other numbers (e.g., 9, 15, 18, etc.).

The twelve keypads constituting the external mount keypad unit 150 are in 4-row and 3-column arrangement, as illustrated in FIG. 2. Accordingly, the plurality of keypads of the external mount keypad unit 150 are generally arranged in M rows and N columns, in which M and N are natural numbers equal to, or greater than 3 and can be appropriately selected depending on the number and arrangement of the keypads.

As illustrated in FIG. 2, it is more preferable to arrange the external mount keypad unit 150 closer to an upper end 111 of the case body 110, rather than to a lower end 112 of the case body 110. One will understand that such arrangement of the external mount keypad unit 150 can allow a user to touch the respective keypads with his or her finger (specifically, a thumb) with increased ease, while holding the protective case 100 attached to the mobile device 10 in his or her hand.

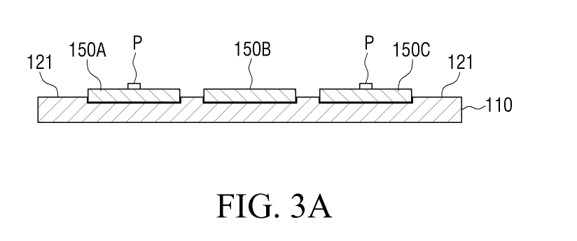

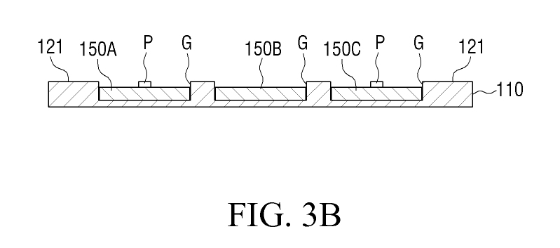

FIG. 3A is a cross sectional view taken on line III-III of the protective case of FIG. 2. As illustrated in FIG. 3A, the first through third keypads 150A, 150B, 150C are button type and are arranged to be externally protruded from the rear surface 121 of the case body 110. That is, the first through third keypads 150A, 150B, 150C are provided in form of buttons which are arranged and protruded from the case body 110. The rest nine keypads, i.e., the fourth through twelfth keypads (150D-150L) also have the sane shape and arrangement as the first through third keypads 150A, 150B, 150C.

As the external mount keypad unit 150 is provided in a form of buttons which are arranged and protruded from the case body 110, the user is able to easily identify the locations of the keypads by touching the same with his or her finger.

FIG. 36 is a cross sectional view similar to FIG. 3A, illustrating an alternative embodiment of the embodiment illustrated in FIG. 3A. As illustrated in FIG. 3B, the first through third keypads 150A, 150B, 150C are provided in the form of buttons, but these are concaved in respective grooves G formed on the rear surface 121 of the case body 110, in which case the rest nine keypads, i.e., the fourth through twelfth keypads 150D-150L are arranged concavely in the respective grooves G in the same manner as the first through third keypads 150A, 150B, 150C.

When the external mount keypad unit 150 is provided in a form of buttons which are arranged and concaved in the case body 110, the user is also able to easily identify the locations of the keypads by touching the same with his or her finger.

Referring to FIGS. 2 and 3A, among the plurality of keypads, and among the three 150A, 150B, 150C that are in the top row, the first and third keypads 150A, 150C may be provided with protrusions P which are formed to assist a user to identify the top from the bottom. The user is able to identify the top from the bottom, or vice versa, due to the presence of the protrusions P. Alternatively, the protrusions P may be respectively provided to the first through third keypads 150A, 150B, 150C, or to the second keypad 150B only, among the first through third keypads 150A, 150B, 150C. Accordingly, the protrusions P may be provided for at least one of the N keypads on the top row.

As an another alternative example, the protrusions P may be formed at the tenth through twelfth keypads 150J, 150K, 150L arranged in a bottom row, respectively, or at the tenth and the twelfth keypads 150J, 150L among the tenth through twelfth keypads 150J, 150K, 150L, or at the eleventh keypad 150K only among the tenth through twelfth keypads 150J, 150K, 150L. These top-down identification protrusions P may be provided in a manner such that at least one of the N keypads arranged in the bottom row is provided with the protrusion P.

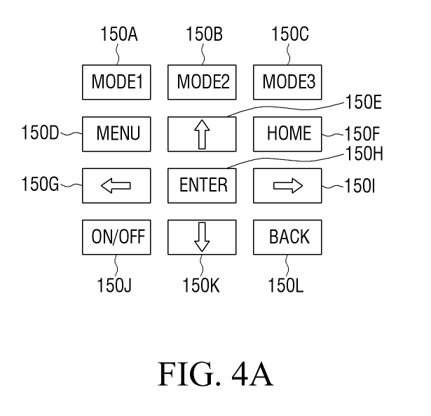

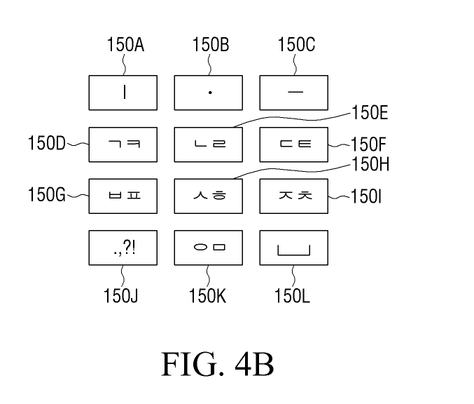

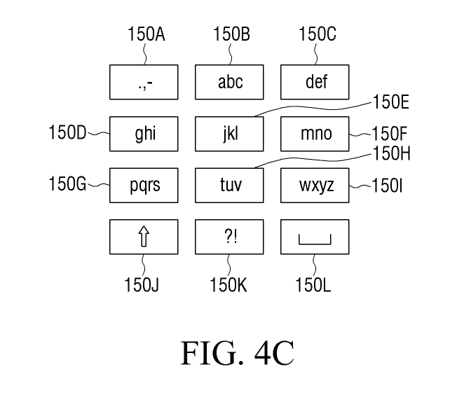

The plurality of keypads 150A-150L of the external mount keypad unit 150 described above may be used in various modes of use. For example, the keypads 150A-150L may be used in three modes of use, as will be explained below with reference to FIGS. 4A, 4B and 4C.

FIG. 4A is a conceptual view illustrating functions designated by keypads when a plurality of keypads shown in FIG. 2 are used in the “first mode”, FIG. 4B is a conceptual view illustrating functions designated by keypads when a plurality of keypads shown in FIG. 2 are used in the “second mode”, and FIG. 4C is a conceptual view illustrating functions designated by keypads when a plurality of keypads shown in FIG. 2 are used in the “third mode”.

The “first mode” herein refers to a mode that is used when the user accesses a desired program or application among the programs and applications of the mobile device. The “second mode” herein refers to a mode that is used when the user intends to input a first language-based text in the mobile device, and the “third mode” herein refers to a mode that is used when the user intends to input a second language-based text in the mobile device. For example, the first language is Korean, and the second language is English.

The user may change the mode of use of the external mount keypad unit 150 anytime. That is, the user may select the desired mode among the first, second and third modes whenever he or she wants.

In an embodiment, the first keypad 150A, the second keypad 150B, and the third keypad 150C are used as mode change keypads each corresponding to the first, second and third modes. For example, in response to the user's long-pressing on the first keypad 150A (e.g., for 1 sec or longer), the external mount keypad unit 150 is set to the first mode.

Alternatively, beside the twelve keypads 150A-150L, a thirteenth keypad (not illustrated) may be additionally provided only for the purpose of performing the mode change function. For example, the external mount keypad unit 150 may be shifted in the order of first mode, second mode and third mode, as the thirteenth keypad is pressed once.

As illustrated in FIG. 4A, when the external mount keypad unit 150 is set to the first mode (i.e., access mode), the first, second and third keypads 150A, 150B, 150C arranged in the top row perform a mode change function. Alternatively, the tenth, eleventh and twelfth keypads 150J, 150K, 150L arranged in the bottom row may perform the mode change function.

The eighth keypad 150H arranged in the center of the third row has an “execute” function. That is, the eighth keypad 150H is the so-called “ENTER” keypad.

Further, centered around the eighth keypad 150, there are the fifth keypad 150E, the eleventh keypad 150K, the seventh keypad 150G and the ninth keypad 150I on the upper, lower, left and right sides and these keypads are used as the up, down, left and right movement keypads. Using these four movement keypads 150E, 150K, 150G, 150I, the user is able to access the desired program or application with ease, and also access desired content easily on the selected program or application. As described, the so-called “navigation” function allows the user to access desired program,application or content using the plurality of movement keypads 150E, 150K, 150G, 150I.

Meanwhile, the fourth keypad 150D, the sixth keypad 150F, the tenth keypad 150J and the twelfth keypad 150L are used as a “MENU” keypad, a “HOME” keypad, a “SCREEN READER ON-OFF” keypad, and a “BACK” keypad. The MENU, HOME and BACK functions refer to the functions used in general keypad units, and will not be described in detail herein. Meanwhile, the SCREEN READER ON-OFF function of the tenth keypad 150J refers to the function of activating or deactivating the screen reader function as provided by the mobile device 10 (see FIG. 1), in which the screen reader function refers to the function by the mobile device 10 of audibly reading the titles or texts corresponding to the program, application or content as this is selected by the user.

As illustrated in FIG. 4B, when the external mount keypad unit 150 is set to the second mode (i.e., first language input mode), the twelve keypads 150A-150L support the input of the first language (Korean in this embodiment). The keyboard combination of the keypads 150A-150L illustrated in FIG. 4B is merely exemplary, and it is of course possible that other Korean keyboard combinations are applied to the keypads 150A-150L. It should be noted that the first keypad 150A, the second keypad 150B and the third keypad 150C arranged in the top row ay still perform mode change function in the second mode. For example, in response to the user pressing the third keypad 150C for shorter than a reference time (e.g., 1 sec), a Korean letter “—” is inputted, and in response to the user pressing the third keypad 150C for longer than the reference time (e.g., 1 sec), the operation is shifted from the second mode to the third mode (i.e., English input mode).

As illustrated in FIG. 4C, when the external mount keypad unit 150 is set to the second mode (i.e., first language input mode), the twelve keypads 150A-150L support the input of the second language (English, in this embodiment). The keyboard combination of the keypads 150A-150L illustrated in FIG. 4C is merely exemplary, and it is of course possible that other English keyboard combinations are applied to the keypads 150A-150L. It should be noted that the first keypad 150A, the second keypad 150B and the third keypad 150C arranged in the top row may still perform mode change function in the third. For example, in response to the user pressing the second keypad 150E for shorter than a reference time (e.g., 1 sec), an English letter “a”, “b” or “c” is inputted, and in response to the user pressing the second keypad 150B for longer than the reference time (e.g., 1 sec), the operation is shifted from the third mode to the second mode (i.e., Korean input mode).

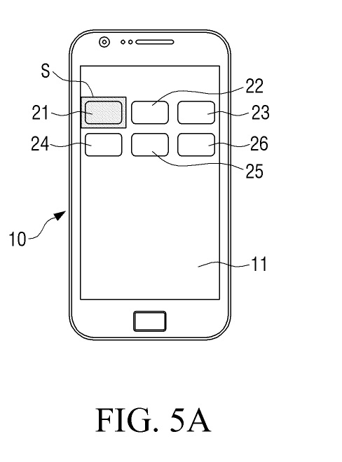

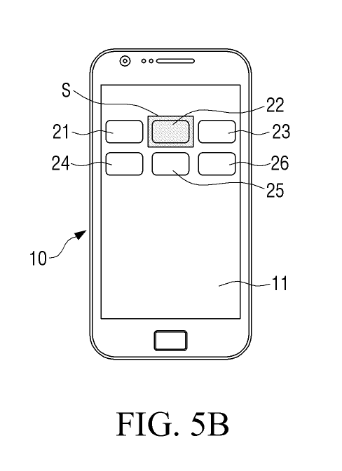

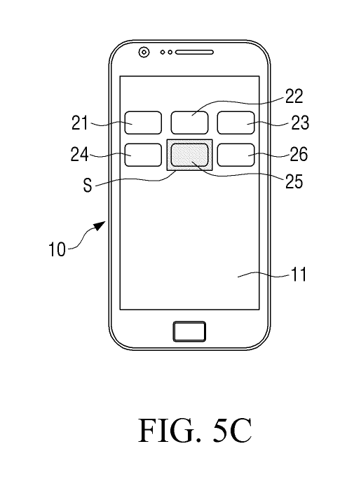

FIGS. 5A, 5B and 5C are plan views of a mobile device, provided to explain a process of approaching a desired program or application using an external mount keypad unit illustrated in FIG. 2.

Referring to FIG. 5A, icons 21-26 corresponding to exemplary applications or folders are arranged on the touch screen 11 of the mobile device 10. For convenience of explanation, the icons 21-26 will be referred to as the first, second, third, fourth, fifth and sixth icons 21 22, 23, 24, 25, 26. Shading S is displayed on the touch screen 11 to indicate a currently-selectable icon, and the shading S initially indicates the first icon 21.

In such a situation, in response to the user who sets the external mount keypad unit 150 to the first mode (i.e. access mode) and presses the ninth keypad 1501 (i.e., right movement keypad), the shading S moves to the fifth icon 25 as illustrated in FIG. 5C. When the screen reader of the mobile device 10 is in operation, the sounds corresponding to the names of the icons are provided from a speaker of the mobile device 10, as the shading S is moved to the second icon 22 and the fifth icon 25 as described above.

With the shading S placed at the fifth icon 25, in response to the user pressing the eighth keypad 150 (i.e., execute keypad), a corresponding program or application designated by the fifth icon 25 is executed, after which the user may access desired content on the executed program or application using the up, down, left and right movement keypads 150E, 150K, 150G, 150I described above. At his time, the target content is indicated by the shading 5, and if the screen reader s in operation, the sound corresponding to the target content is provided from the speaker of the mobile device 10. At this time, if the user intends to input the first language (i.e., Korean)-based text, the user may shift the external mount keypad unit 150 to the second mode (i.e., first language input mode) by pressing the second keypad 150B. If the user intends to input the second language (i.e., English)-based text, the user may shift the external mount keypad unit 150 to the third mode (i.e., second language input mode) by pressing the third keypad 150B.

If the user wants to exit h program or application designated by the fifth icon 25, the user may shift the mode of use of the external mount keypad unit 150 to the first mode (i.e., access mode) by pressing the first keypad 150A, and use the sixth keypad 150F which is the “HOME” keypad, or the twelfth keypad 150L which is the “BACK” keypad.

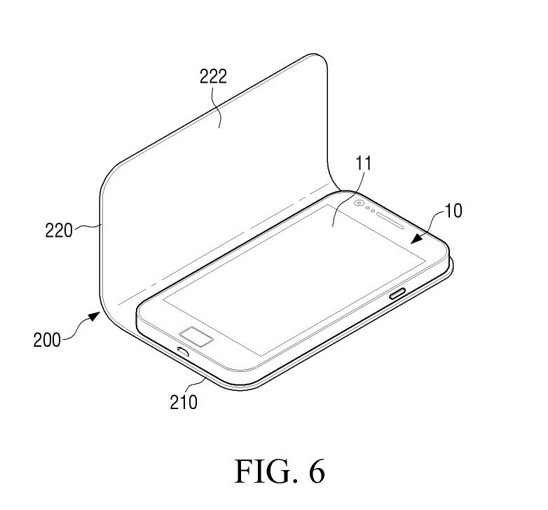

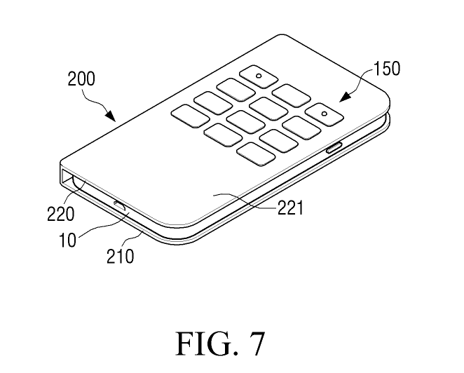

FIG. 6 is a perspective view of a protective case for a mobile device according to a second embodiment of the present disclosure, shown along with the mobile device, and FIG. 7 is a perspective view of the protective case of FIG. 6 in closed state.

Referring to FIGS. 6 and 7, the protective case 200 according to the second embodiment includes a rear cover 210 and a front cover 220. The rear cover 210 is attached onto the mobile device 10, covering a rear surface of the mobile device 10, and the front cover 220 is integrally provided on the rear cover 210, covering a front surface of the mobile device 10 when in closed state.

As described, the protective case 200 according to the second embodiment, which is the so-called ‘double-surface cover type’ that covers both the front and rear surfaces of the mobile device 10, is distinguished from the protective case 100 (see FIG. 1) described above which is the so-called ‘rear-surface cover type’ covers only the rear surface of the mobile device 10.

As illustrated in FIG. 7, the external mount keypad unit 150 is provided on a front surface 221 (i.e., outer surface) of the front cover 220 of the protective case 200, which is identical to the example of the external mount keypad unit 150 described above with reference to FIG. 2. Alternatively, the external mount keypad unit 150 may be provided on a rear surface 222 (i.e., inner surface) of the front cover 220, or on a rear surface (i.e., outer surface) (not illustrated in the drawings) of the rear cover 210. As illustrated in FIG. 7, the external mount keypad unit 150 is arranged on the front surface 221 of the front cover 220, while being relatively lopsided toward the top, thus allowing the user to access all the keypads in the external mount keypad unit 150 with his or her finger (e.g., thumb) with increased ease, while holding the protective case 200 in his or her hand.

With the protective case 100, 200 for a mobile device according to the first and second embodiments described above, those with visual disabilities or those who are restricted from watching the mobile device can easily use the mobile device 100 using the external mount keypad unit 150 provided on the protective case 100, 200, without having to use the touch screen 11 on the mobile device 10.

Since the external mount keypad unit 150 is integrally provided with general protective case 100, 200, rather than being provided as a separate article, there is no inconvenience of having to carry around the separate article, and accessibility to the keypad unit 150 can also be enhanced.

### INDUSTRIAL APPLICABILITY

The present disclosure relates to a protective case for a mobile device having an external mount keypad unit.

1. A protective case for a mobile device, comprising:
a case body attached to the mobile device; and
an external mount keypad unit provided on the case body, and comprising a plurality of keypads for use of the mobile device.

2. The protective case of claim 1, wherein the plurality of keypads are arranged in M rows and N columns, wherein M and N are natural numbers which are equal to, or greater than 3.

3. The protective case of claim 2, wherein at least one of the keypads arranged on a top row or a bottom row among the plurality of keypads is provided with a protrusion to assist identification of a top of the external mount keypad unit from a bottom thereof.

4. The protective case of claim 3, wherein the keypads arranged in a left-most side and in a right-most side among the N number of keypads arranged in the top row or the bottom row, are provided with the protrusion.

5. The protective case of claim 1, wherein the plurality of keypads are used in any one of a first mode to access a program or an application of the mobile device, a second mode to input a first language-based text, and a third mode to input a second language-based text.

6. The protective case of claim 5, wherein the plurality of keypads are arranged in 4 rows and 3 columns.

7. The protective case of claim 6, wherein, when the plurality of keypads are used in the first mode, four out of the plurality of keypads are used as up, down, left and right movement keypads.

8. The protective case of claim 7, wherein, when the plurality of keypads are used in the first mode, the up, down, left and right movement keypads are arranged on an upper side, a lower side, a left side and a right side with reference to any one of the plurality of keypads.

9. The protective case of claim 1, wherein the case body is a rear surface cover type which covers a rear surface of the mobile device.

10. The protective case of claim 9, wherein the external mount keypad unit is provided on a rear surface of the case body.

11. The protective case of claim 10, wherein the external mount keypad unit is arranged closer to an upper end than to a lower end, on the rear surface of the case body.

12. The protective case of claim 1, wherein the case body is a double surface cover type which covers a front surface and a rear surface of the mobile device.

13. The protective case of claim 12, wherein the case body comprises:
a rear cover attached to the mobile device, covering a rear surface of the mobile device; and
a front cover covering a front surface of the mobile device.

14. The protective case of claim 13, wherein the external mount keypad unit is provided on any one of a rear surface of the rear cover, a front surface of the front cover, and a rear surface of the front cover.

15. The protective case of claim 1, wherein the plurality of keypads are protruded from the case body or concaved within the case body.
